(19) United States
(12) Patent Application Publication
(10) Pub. No.: US 2017/0204506 A1
(43) Pub. Date: Jul. 20, 2017

(54) MASK PLATE

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventor: Jian ZHANG, Beijing (CN)

(21) Appl. No.: 15/321,522

(22) PCT Filed: Mar. 3, 2016
(86) PCT No.: PCT/CN2016/075474

§ 371 Date: Dec. 22, 2016

(30) Foreign Application Priority Data
Mar. 20, 2015 (CN) 201510125791.5

(51) Int. Cl. C23C 14/04

(52) U.S. Cl. CPC C23C 14/042; H01L 51/001

(57) ABSTRACT

The embodiments of the present invention provide a mask plate for preparing active organic electroluminescent devices, eliminating the problem of color mixing caused by the deformation of the mask plate in the prior art, improving the evaporation quality. The mask plate comprises a plurality of evaporation units arranged along the same arrangement direction; each evaporation unit is provided with a plurality of evaporation gaps arranged regularly. A shape of the evaporation gaps in at least one evaporation unit is different with that of the evaporation gaps in other evaporation units. By flexibly arranging two kinds of evaporation units having evaporation gaps with different shapes, these two kinds of evaporation units reduce stress for each other, effectively eliminating the deformation of mask plate caused by homogeneous evaporation units, thereby solving the problem of color mixing caused by the deformation of the mask plate in the prior art, improving the evaporation quality.

### TECHNICAL FIELD

The present invention relates to the field of electroluminescent display technology, in particular to a mask for preparing active organic electroluminescent devices.

### BACKGROUND

Flat panel display includes LCD (liquid crystal display), OLED (organic light emitting diode) display and PDP (plasma display panel) display, electronic ink display and so on. Since OLED display has the advantages of lightweight, low power consumption, high contrast, high color gamut, and flexibility, it is the development trend of the next generation display. OLED display includes PMOLED (passive matrix/organic light emitting diode) display and AMOLED (active matrix/organic light emitting diode) display; an implementation for AMOLED display includes a “LTPS (low temperature poly-silicon) backplane+FMM (fine metal mask)” mode, and a “semiconductor oxide backplane+WOLED (white organic light emitting diode)+color film” mode. The former is mainly used in small size panels, corresponding to mobile phones and mobile applications; the latter is mainly used in large size panels, corresponding to display and TV applications. Nowadays the “LTPS backplane+FMM” mode is initially mature to achieve mass production.

The mode of Fine Metal Mask includes forming OLED material on an LTPS backplane with predetermined program of evaporation plating, and forming RGB devices using patterns on the FMM. Referring to FIG. 1 and FIG. 2, in the prior art, a mask plate applied for AMOLED is typically a slit type mask plate or a dot type mask plate with a homogeneous structure; a metal mask plate includes a plurality of evaporation unit; the evaporation unit includes a plurality of regularly arranged evaporation gaps; the shape of an evaporation gap in a slit type mask plate is a slit; the shape of an evaporation gap in a dot type mask plate is a dot. However, since stress in a single mask plate with a homogeneous structure is not uniform, the evaporation units in a single mask plate have deformation with different degrees; after evaporation, color mixing is apt to occur at edges of each evaporation unit, affecting the evaporation quality.

### SUMMARY

The embodiments of the present invention provide a mask plate for preparing active organic electroluminescent devices, eliminating the problem of color mixing caused by the deformation of the mask plate in the prior art, improving the evaporation quality.

An embodiment of the present invention provides a mask plate for preparing active organic electroluminescent devices. The mask plate comprises a plurality of evaporation units arranged along the same arrangement direction; each evaporation unit is provided with a plurality of evaporation gaps arranged regularly. A shape of the evaporation gaps in at least one evaporation unit is different with that of the evaporation gaps in other evaporation units.

In the embodiment of the present invention, a shape of the evaporation gaps in at least one evaporation unit is different with that of the evaporation gaps in other evaporation units. By flexibly arranging two kinds of evaporation units having evaporation gaps with different shapes, these two kinds of evaporation units reduce stress for each other, effectively eliminating the deformation of mask plate caused by homogeneous evaporation units, thereby solving the problem of color mixing caused by the deformation of the mask plate in the prior art, improving the evaporation quality.

Optionally, in the plane of the mask plate, with a line passing through the center of the mask plate and perpendicular to the arrangement direction of the plurality of evaporation units as an axis of symmetry, the shapes of the evaporation gaps in two symmetrical evaporation units are same. For two evaporation units on symmetrical positions, the deformation quantities at symmetrical positions on the mask plate are same. Therefore, the rectification quantities required for these evaporation units are same, shortening the time required for rectification and the process period.

Optionally, the plurality of evaporation units have the same size. By arranging a plurality of evaporation units with the same size on a mask plate, customer requirement on two display screens with the same size and different types of structures can be fulfilled. Moreover, the product quality can be guaranteed and promoted.

Optionally, the shape of the evaporation gaps in the evaporation units is a dot or a slit. If the shape of the evaporation gaps is a dot, a high pixel density can be achieved through the arrangement of the dots and the back circuit control. If the shape of the evaporation gaps is a slit, the metal portion is relatively small in the mask plate, the space between the metal wires is relatively large, and the aperture ratio is high.

Optionally, the mask plate comprises 5 evaporation units. To improve the utilization of a glass substrate, cutting in the form of n (line)×5 (column) is typically applied; in evaporation process, the glass substrates are also arranged in the form of n (line)×5 (column). Therefore, a mask plate with 5 evaporation units meets the requirements of the majority of evaporation processes.

Optionally, the shape of the evaporation gaps in the first evaporation unit, the third evaporation unit and the fifth evaporation unit is a slit; the shape of the evaporation gaps in the second evaporation unit and the fourth evaporation unit is a dot. Optionally, in each of the first evaporation unit, the third evaporation unit and the fifth evaporation unit, an arrangement direction of the evaporation gaps is perpendicular to the arrangement direction of the plurality of evaporation units. If the shape of the evaporation gaps in the first evaporation unit, the third evaporation unit and the fifth evaporation unit is a slit, and the shape of the evaporation gaps in the second evaporation unit and the fourth evaporation unit is a dot, each evaporation unit on the stretched mask plate has deformation of the same trend. After determining the width for the stretched mask plate, generally appropriate mask plates can be purchased, and the rectification for the mask plate can be achieved with one or two trials. The rectification efficiency for the mask plate is then improved effectively, shortening the rectification period for the mask plate and improving the productivity.

Optionally, the shape of the evaporation gaps in the first evaporation unit and the fifth evaporation unit is a slit; the shape of the evaporation gaps in the second evaporation unit, the third evaporation unit and the fourth evaporation unit is a dot. Optionally, in each of the first evaporation unit and the fifth evaporation unit, an arrangement direction of the evaporation gaps is perpendicular to the arrangement direction of the plurality of evaporation units. A mask plate with dot type evaporation units and slit type evaporation units arranged alternatively may not control color mixing in a region well, which region corresponds to a central evaporation unit with slit type evaporation gap. Since retraction of the central portion on a mask plate with dot structure is not significant, the shape of the evaporation gaps in the third evaporation unit located in the central portion can then be set as a dot shape. In this way, the deformation of the third evaporation unit can further be reduced, ensuring a good shape for the third evaporation unit, further avoiding color mixing in a region of a substrate corresponding to the third evaporation unit.

Optionally, the shape of the evaporation gaps in the first evaporation unit and the fifth evaporation unit is a dot; the shape of the evaporation gaps in the second evaporation unit, the third evaporation unit and the fourth evaporation unit is a slit. Optionally, in each of the second evaporation unit, the third evaporation unit and the fourth evaporation unit, an arrangement direction of the evaporation gaps is perpendicular to the arrangement direction of the plurality of evaporation units. Since the metal portion is relatively large in a mask plate with dot structure, such a mask plate has the property of weak expansion and little shrinkage; therefore, for a mask plate with large deformation at both ends and small deformation at the central region, applying evaporation unit with dot type evaporation gaps at both ends can effectively reduce the degree of relaxation at both ends, reducing the deformation of the mask plate.

Optionally, the shape of the evaporation gaps in the first evaporation unit, the third evaporation unit and the fifth evaporation unit is a dot; the shape of the evaporation gaps in the second evaporation unit and the fourth evaporation unit is a slit. Optionally, in each of the second evaporation unit and the fourth evaporation unit, an arrangement direction of the evaporation gaps is perpendicular to the arrangement direction of the plurality of evaporation units. Since the evaporation unit with slit type evaporation gaps has property of relaxation on both ends, for a homogeneous mask plate of dot type, the shrinkage of the evaporation units at both ends is relatively large after being stretched, and the color mixing is severe. By arranging the shape of the evaporation gaps in the second evaporation unit and the fourth evaporation unit as a slit, the shrink trend of the regions on both ends can be reduced after being stretched, reducing the deformation of the mask plate.

Optionally, the material of the mask plate is invar alloy. Compared with other materials, invar alloy has advantages of resistance to high temperature and high pressure, low expansion coefficient and little deformation etc., therefore the mask plate prepared with invar alloy material can be applied in evaporation process; in addition, other metal materials with resistance to high temperature and high pressure, low expansion coefficient and stable form can also be used for preparing the mask plate.

### BRIEF DESCRIPTION OF THE DRAWINGS

FIG. 1 is a schematic diagram of planar structure for a slit type mask plate in the prior art;

FIG. 2 is a schematic diagram of planar structure for a dot type mask plate in the prior art;

FIG. 3 is a schematic diagram of planar structure for a mask plate according to a first embodiment of the present invention;

FIG. 4 is a schematic diagram of planar structure for an entire mask plate formed with a plurality of single mask plates;

FIG. 5 is a schematic diagram of planar structure for a mask plate according to a second embodiment of the present invention;

FIG. 6 is an effect drawing of a homogeneous slit type mask plate after being stretched;

FIG. 7 is an effect drawing of a mask plate according to the second embodiment of the present invention after being stretched;

FIG. 8 is a schematic diagram of planar structure for a mask plate according to a third embodiment of the present invention;

FIG. 9 is a schematic diagram of planar structure for a mask plate according to a fourth embodiment of the present invention;

FIG. 10 is a schematic diagram of planar structure for a mask plate according to a fifth embodiment of the present invention; and

FIG. 11 is an effect drawing of a homogeneous dot type mask plate after being stretched.

### DETAILED DESCRIPTION OF THE INVENTION

The embodiments of the present invention provide a mask plate for preparing active organic electroluminescent devices, eliminating the problem of color mixing caused by the deformation of the mask plate in the prior art, improving the evaporation quality.

In the following, the technical solutions in embodiments of the invention will be described clearly and completely in connection with the drawings in the embodiments of the invention. Obviously, the described embodiments are only part of the embodiments of the invention, and not all of the embodiments. Based on the embodiments in the invention, all other embodiments obtained by those of ordinary skills in the art under the premise of not paying out creative work pertain to the protection scope of the invention.

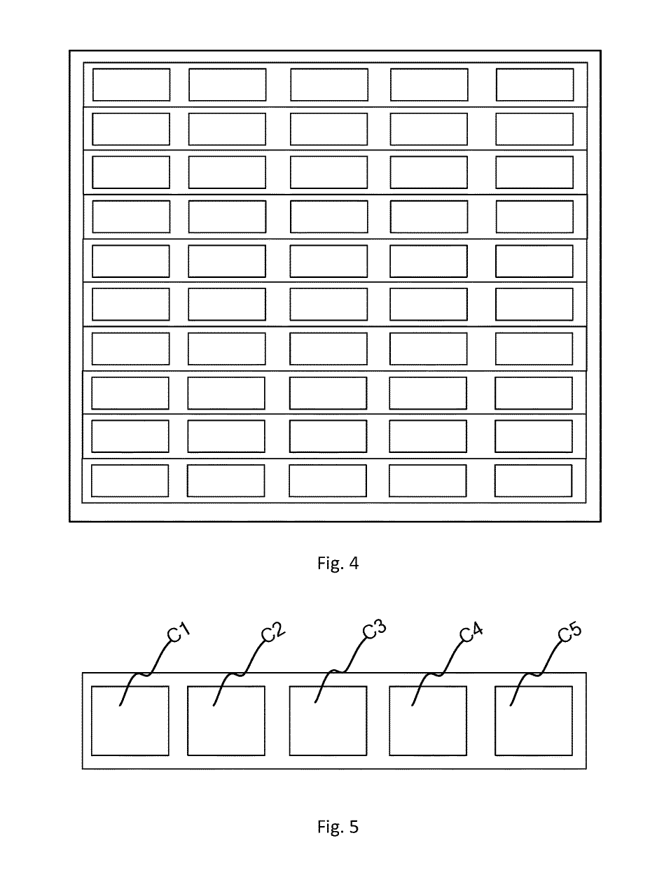

A first embodiment of the present invention provides a mask plate for preparing active organic electroluminescent devices. As shown in FIG. 3, the mask plate comprises a plurality of evaporation units C arranged along the same arrangement direction; each evaporation unit C is provided with a plurality of evaporation gaps arranged regularly. A shape of the evaporation gaps in at least one evaporation unit is different with that of the evaporation gaps in other evaporation units.

Further, in the plane of the mask plate, with a line passing through the center of the mask plate and perpendicular to the arrangement direction of the plurality of evaporation units as an axis of symmetry, the shapes of the evaporation gaps in two symmetrical evaporation units are same. For two evaporation units on symmetrical positions, the deformation quantities at symmetrical positions on the mask plate are same. Therefore, the rectification quantities required for these evaporation units are same, shortening the time required for rectification and the process period.

Further, the plurality of evaporation units have the same size. By arranging a plurality of evaporation units with the same size on a mask plate, customer requirement on two display screens with the same size and different types of structures can be fulfilled. Moreover, the product quality can be guaranteed and promoted.

Further, the shape of the evaporation gaps in the evaporation units is a dot or a slit. If the shape of the evaporation gaps is a dot, a high pixel density can be achieved through the arrangement of the dots and the back circuit control. If the shape of the evaporation gaps is a slit, the metal portion is relatively small in the mask plate, the space between the metal wires is relatively large, and the aperture ratio is high.

Further, the mask plate comprises 5 evaporation units. To improve the utilization of a glass substrate, cutting in the form of n (line)×5 (column) is typically applied; in evaporation process, the glass substrates are also arranged in the form of n (line)×5 (column). Therefore, a mask plate with 5 evaporation units meets the requirements of the majority of evaporation processes. For example, in the fifth generation production line, generally a large glass is firstly divided into 4 small pieces of glass; then each small piece of glass is cut in a form of 10×5, into 50 pieces of 5 inch screens, thereby maximizing the utilization ratio of the glass substrate. Therefore, as shown in FIG. 4, after being stretched, 10 mask plates can be fixed on a peripheral frame; each of the mask plate comprises evaporation units of 5 inch. After evaporation is completed, the glass substrate with a size equal to the area of 10 mask plates can be cut in a form of 10×5, into 50 pieces of 5 inch screens.

Further, in an embodiment of the present invention, the material of the mask plate is invar alloy. Compared with other materials, invar alloy has advantages of resistance to high temperature and high pressure, low expansion coefficient and little deformation etc., therefore the mask plate prepared with invar alloy material can be applied in evaporation process; in addition, other metal materials with resistance to high temperature and high pressure, low expansion coefficient and stable form can also be used for preparing the mask plate.

A second embodiment of the present invention provides a mask plate. As shown in FIG. 5, the mask plate comprises 5 evaporation units. The shape of the evaporation gaps in the first evaporation unit C1, the third evaporation unit C3 and the fifth evaporation unit C5 is a slit; the shape of the evaporation gaps in the second evaporation unit C2 and the fourth evaporation unit C4 is a dot. Optionally, in each of the first evaporation unit C1, the third evaporation unit C3 and the fifth evaporation unit C5, an arrangement direction of the evaporation gaps is perpendicular to the arrangement direction of the plurality of evaporation units.

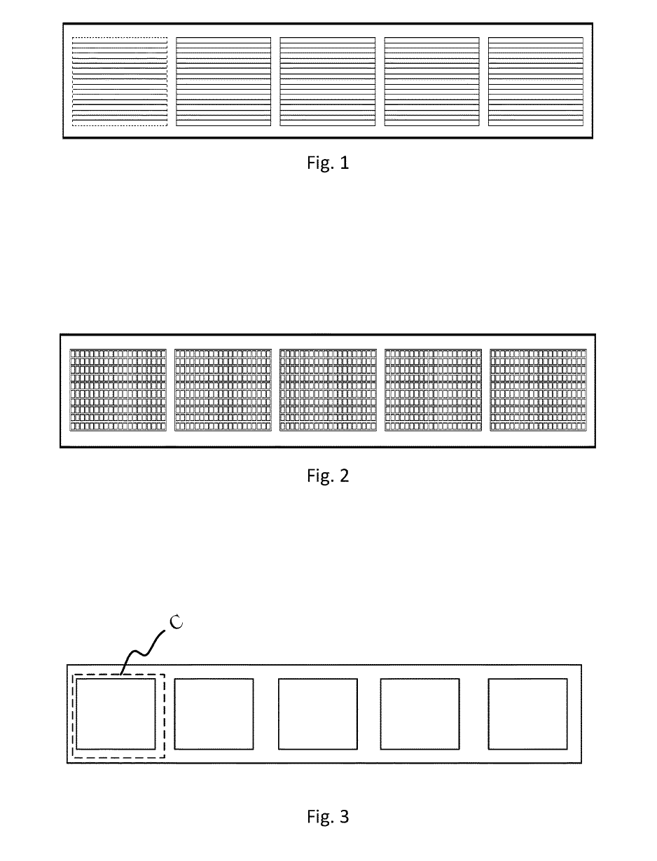

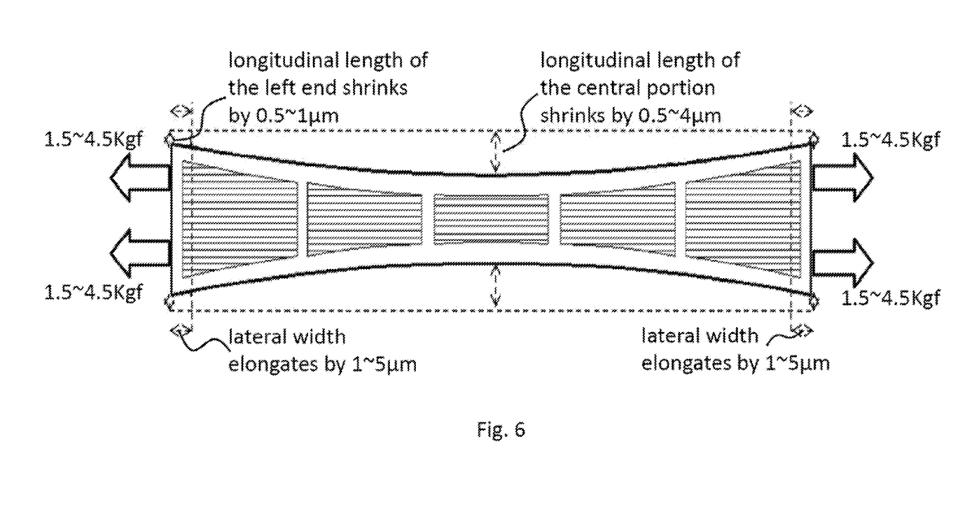

A single invar alloy mask plate with 5 evaporation units arranged in a symmetric structure has a size of 600 mm˜1200 mm long, 50 mm˜100 mm wide, and 20 μm˜50 μm thick. The mask plate is stretched with a force of 3˜9 Kg at the left and right ends. The mask plate before being stretched is shown in FIG. 1; the mask plate after being stretched is shown in FIG. 6. After being stretched, the central evaporation unit is deformed inwards; the longitudinal length shrinks by 1˜8 μm. Towards the left and right ends, the shrink trend reduces gradually to 1˜2 μm. The lateral width elongates by 2˜10 μm. Therefore, after a homogeneous slit type mask plate is stretched, the deformation trends of the evaporation units are different with each other. In purchase of the mask plate, a large reserved stretching amount should be considered; it is also difficult to grasp the size and law of the reserved stretching amount. For example, to obtain a stretched mask plate with a uniform width of 50 mm, rectification is required for each evaporation unit; the rectification amounts for the evaporation units are different with each other. Moreover, the rectification amounts for different positions in a single evaporation unit are different. Satisfactory mask plates can only be obtained after a long consultation with the mask plate manufacturer. For the mask plate of this example, after the rectification, the longitudinal length on both ends is 49.999 mm; the longitudinal length of the central portion is 50.004 mm. To obtain the rectification amount of the central portion, a lot of stretching tests are required. Finally, a stretched mask plate with a width of 50 mm can be obtained.

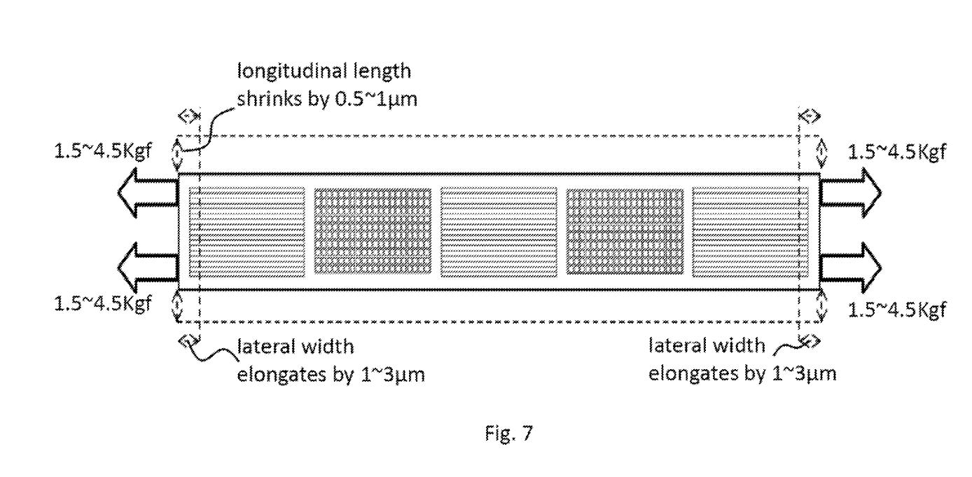

A single invar alloy mask plate with 5 evaporation units arranged in a symmetric structure is provided by an embodiment of the present invention; the mask plate has a size of 600 mm˜1200 mm long, 50 mm˜100 mm wide, and 20 μm˜50 μm thick. The mask plate is stretched with a force of 3˜9 Kg at the left and right ends. The mask plate before being stretched is shown in FIG. 5; the mask plate after being stretched is shown in FIG. 7. After being stretched, the deformation throughout the mask plate is uniform; the longitudinal length shrinks by 1˜2 μm; the shrink trends of the evaporation units are same. The lateral width elongates by 2˜4 μm. Therefore, after the mask plate with such a structure is stretched, the deformation trends of the evaporation units are same to each other. In purchase of the mask plate, a stretching amount can thus be reserved. For example, to obtain a stretched mask plate with a uniform width of 50 mm, a mask plate with an overall width of 49.998 mm should be used; then a desired size can be obtained after stretching.

In an embodiment of the present invention, the shape of the evaporation gaps in the first evaporation unit, the third evaporation unit and the fifth evaporation unit is a slit, and the shape of the evaporation gaps in the second evaporation unit and the fourth evaporation unit is a dot, each evaporation unit on the stretched mask plate has deformation of the same trend. After determining the width for the stretched mask plate, generally appropriate mask plates can be purchased, and the rectification for the mask plate can be achieved with one or two trials. The rectification efficiency for the mask plate is then improved effectively, shortening the rectification period for the mask plate and improving the productivity. In addition, by solving the problem of color mixing, the problem of pixel density caused by color mixing is also resolved. Therefore, if the deformation of the mask plate is reduced, the number of pixels can further be increased, meeting the requirements of preparing mask plate with high precision and AMOLED display with high pixel density. Moreover, since the mask plate comprises dot type evaporation unit and slit type evaporation unit, the mask plate can meet requirements on dot type mask plate and slit type mask plate; the evaporation quality can also be guaranteed and improved.

A third embodiment of the present invention provides a mask plate. As shown in FIG. 8, the mask plate comprises 5 evaporation units. The shape of the evaporation gaps in the first evaporation unit C1 and the fifth evaporation unit C5 is a slit; the shape of the evaporation gaps in the second evaporation unit C2, the third evaporation unit C3 and the fourth evaporation unit C3 is a dot. Optionally, in each of the first evaporation unit C1 and the fifth evaporation unit C5, an arrangement direction of the evaporation gaps is perpendicular to the arrangement direction of the plurality of evaporation units.

A mask plate with dot type evaporation units and slit type evaporation units arranged alternatively may not control color mixing in a region well, which region corresponds to a central evaporation unit with slit type evaporation gap. Since retraction of the central portion on a mask plate with dot structure is not significant, the shape of the evaporation gaps in the third evaporation unit C3 located in the central portion can then be set as a dot shape. In this way, the deformation of the third evaporation unit C3 can further be reduced, ensuring a good shape for the third evaporation unit, further avoiding color mixing in a region of a substrate corresponding to the third evaporation unit C3.

A fourth embodiment of the present invention provides a mask plate. As shown in FIG. 9, the mask plate comprises 5 evaporation units. The shape of the evaporation gaps in the first evaporation unit C1 and the fifth evaporation unit C5 is a dot; the shape of the evaporation gaps in the second evaporation unit C2, the third evaporation unit C3 and the fourth evaporation unit C4 is a slit. Optionally, in each of the second evaporation unit C2, the third evaporation unit C3 and the fourth evaporation unit C4, to an arrangement direction of the evaporation gaps is perpendicular to the arrangement direction of the plurality of evaporation units.

Since the metal portion is relatively large in a mask plate with dot structure, such a mask plate has the property of weak expansion and little shrinkage; therefore, for a mask plate with large deformation at both ends and small deformation at the central region, applying evaporation unit with dot type evaporation gaps at both ends can effectively reduce the degree of relaxation at both ends, reducing the deformation of the mask plate.

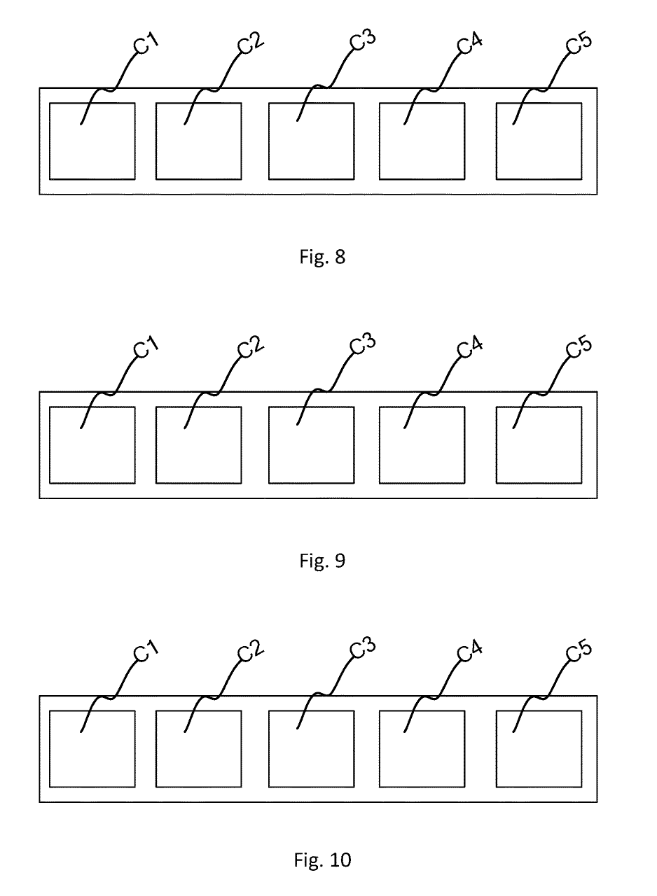

A fifth embodiment of the present invention provides a mask plate. As shown in FIG. 10, the mask plate comprises 5 evaporation units. The shape of the evaporation gaps in the first evaporation unit C1, the third evaporation unit C3 and the fifth evaporation unit C5 is a dot; the shape of the evaporation gaps in the second evaporation unit C2 and the fourth evaporation unit C4 is a slit. Optionally, in each of the second evaporation unit C2 and the fourth evaporation unit C4, an arrangement direction of the evaporation gaps is perpendicular to the arrangement direction of the plurality of evaporation units.

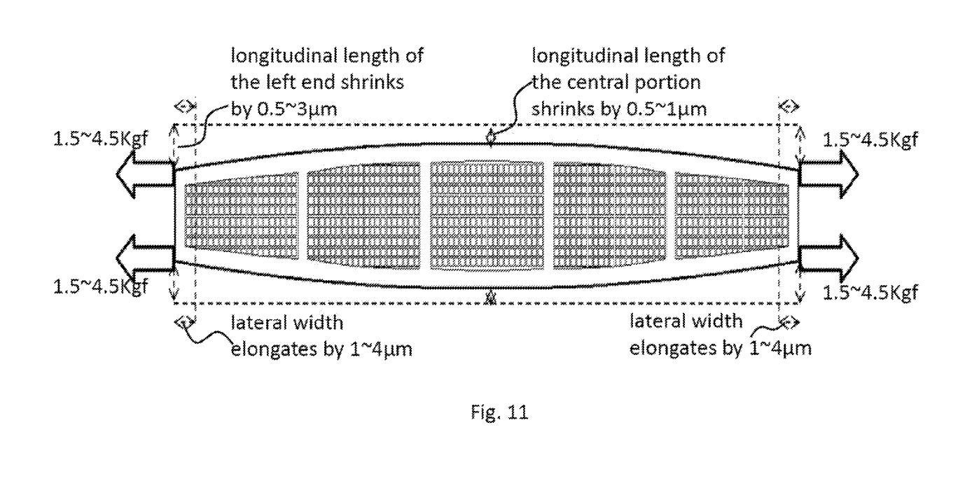

Though, the metal portion is relatively large in a mask plate with dot structure, and such a mask plate has the property of weak expansion and little shrinkage, a homogeneous mask plate of dot type is still apt to deform. For example, a single mask plate having a size of 600 mm˜1200 mm long, 50 mm˜100 mm wide, and 20 μm˜50 μm thick is stretched with a force of 3˜9 Kg at the left and right ends; the mask plate is an invar alloy mask plate with 5 evaporation units arranged in a symmetric structure. The mask plate before being stretched is shown in FIG. 2; the mask plate after being stretched is shown in FIG. 11. After being stretched, the evaporation units on both ends are deformed inwards; the longitudinal length shrinks by 1˜6 μm. Towards the central portion, the shrink trend reduces gradually to 1˜2 μm. The lateral width elongates by 2˜8 μm. Therefore, after a homogeneous dot type mask plate is stretched, the deformation trends of the evaporation units are different with each other' The deformation of the first evaporation unit and the fifth evaporation unit is relatively large; after evaporation, color mixing in a region of a substrate corresponding to these evaporation units is severe. In purchase of the mask plate, a large reserved stretching amount should be considered; it is also difficult to grasp the size and law of the reserved stretching amount. Satisfactory mask plates can only be obtained after a long consultation with the mask plate manufacturer; a lot of rectification tests are also required, prolonging the process period.

In the fifth embodiment of the present invention, the shape of the evaporation gaps in the second evaporation unit and the fourth evaporation unit is a slit. Since the evaporation unit with slit type evaporation gaps has property of relaxation on both ends, the shrink trends of the stretched first evaporation unit and the fifth evaporation unit are reduced. In such a manner, the deformation of the mask plate is reduced, solving the problem of color mixing caused by deformation.

In conclusion, the embodiments of the present invention provide a mask plate for preparing active organic electroluminescent devices. In the mask plate, a shape of the evaporation gaps in at least one evaporation unit is different with that of the evaporation gaps in other evaporation units. By flexibly arranging two kinds of evaporation units having evaporation gaps with different shapes, these two kinds of evaporation units reduce stress for each other, effectively eliminating the deformation of mask plate caused by homogeneous evaporation units, thereby solving the problems of color mixing, low pixel density and long preparation period caused by the deformation of the mask plate in the prior art, improving the evaporation quality and pixel density, shortening the preparation period.

Apparently, the person skilled in the art may make various alterations and variations to the invention without departing the spirit and scope of the invention. As such, provided that these modifications and variations of the invention pertain to the scope of the claims of the invention and their equivalents, the invention is intended to embrace these alterations and variations.

What is claimed is:

1. A mask plate comprising a plurality of evaporation units arranged along the same arrangement direction, each evaporation unit provided with a plurality of evaporation gaps arranged regularly; a shape of the evaporation gaps in at least one evaporation unit being different with that of the evaporation gaps in other evaporation units.

2. The mask plate according to claim 1, wherein in the plane of the mask plate, with a line passing through the center of the mask plate and perpendicular to the arrangement direction of the plurality of evaporation units as an axis of symmetry, the shapes of the evaporation gaps in two symmetrical evaporation units are same.

3. The mask plate according to claim 1, wherein the plurality of evaporation units have the same size.

4. The mask plate according to claim 1, wherein the shape of the evaporation gaps in the evaporation units is a dot or a slit.

5. The mask plate according to claim 1, wherein the mask plate comprises 5 evaporation units.

6. The mask plate according to claim 5, wherein the shape of the evaporation gaps in the first evaporation unit, the third evaporation unit and the fifth evaporation unit is a slit; the shape of the evaporation gaps in the second evaporation unit and the fourth evaporation unit is a dot.

7. The mask plate according to claim 6, wherein in each of the first evaporation unit, the third evaporation unit and the fifth evaporation unit, an arrangement direction of the evaporation gaps is perpendicular to the arrangement direction of the plurality of evaporation units.

8. The mask plate according to claim 5, wherein the shape of the evaporation gaps in the first evaporation unit and the fifth evaporation unit is a slit; the shape of the evaporation gaps in the second evaporation unit, the third evaporation unit and the fourth evaporation unit is a dot.

9. The mask plate according to claim 8, wherein in each of the first evaporation unit and the fifth evaporation unit, an arrangement direction of the evaporation gaps is perpendicular to the arrangement direction of the plurality of evaporation units.

10. The mask plate according to claim 5, wherein the shape of the evaporation gaps in the first evaporation unit and the fifth evaporation unit is a dot; the shape of the evaporation gaps in the second evaporation unit, the third evaporation unit and the fourth evaporation unit is a slit.

11. The mask plate according to claim 10, wherein in each of the second evaporation unit, the third evaporation unit and the fourth evaporation unit, an arrangement direction of the evaporation gaps is perpendicular to the arrangement direction of the plurality of evaporation units.

12. The mask plate according to claim 5, wherein the shape of the evaporation gaps in the first evaporation unit, the third evaporation unit and the fifth evaporation unit is a dot; the shape of the evaporation gaps in the second evaporation unit and the fourth evaporation unit is a slit.

13. The mask plate according to claim 12, wherein in each of the second evaporation unit and the fourth evaporation unit, an arrangement direction of the evaporation gaps is perpendicular to the arrangement direction of the plurality of evaporation units.

14. The mask plate according to claim 1, wherein the material of the mask plate is invar alloy.
